(19) United States
(12) Patent Application Publication
(10) Pub. No.: US 2012/0007117 A1
(43) Pub. Date: Jan. 12, 2012

(54) Submount for Electronic Die Attach with Controlled Voids and Methods of Attaching an Electronic Die to a Submount Including Engineered Voids

(76) Inventor: Peter S. Andrews, Durham, NC (US)

(21) Appl. No.: 13/178,732

(22) Filed: Jul. 8, 2011

Related U.S. Application Data
(60) Provisional application No. 61/362,428, filed on Jul. 8, 2010.

(51) Int. Cl. H01L 33/60; B23K 1/20; H01L 23/48

(52) U.S. Cl. 257/98; 257/782; 228/214; 257/E33.072; 257/E23.01

(57) ABSTRACT

A packaged electronic device includes a submount, a bonding pattern on the submount, and an electronic chip on the bonding pattern. A periphery of the electronic chip defines a die mounting region of the submount. The bonding pattern includes a bonding area within the die mounting region and at least one channel that extends from within the die mounting region to a region of the submount outside the die mounting region.

### RELATED APPLICATIONS

The present application claims the benefit of and priority to U.S. Provisional Patent Application No. 61/362,428, filed Jul. 8, 2010, entitled “Submount for Electronic Die Attach with Controlled Voids and Methods of Attaching an Electronic Die to a Submount Including Engineered Voids,” the disclosure of which is hereby incorporated herein by reference in its entirety.

### FIELD

The present invention relates to electronic device packaging, and more particularly, to submounts for mounting electronic devices and methods of mounting electronic devices on submounts.

### BACKGROUND

Electronic devices, such as light emitting diodes (LEDs) may be mounted onto submounts that may provide electrical contact to the electronic devices, as well as acting as a thermal pathway for the removal of heat from the device. Soldering is a well known technique for joining metal surfaces, and has been used for attaching electronic devices to conductive traces or pads on submounts. In particular, soldering can provide a robust, electrically conductive connection between an electronic device and a submount.

The term “solder” refers a metal alloy that typically has a melting point between about 90° C. and 450° C. Such an alloy can be deposited onto an electronic device before attachment of the device to the submount. For example, an LED may include a metal stack including a solderable metal, such as the metal stacks described in U.S. Pat. No. 7,642,121 to Slater et al. entitled “LED Bonding Structures And Methods Of Fabricating LED Bonding Structures,” U.S. Pat. No. 7,259,033 to Slater et al. entitled “Flip-Chip Bonding Of Light Emitting Devices,” and U.S. Publication No. 2007/0161137 entitled “Methods of Manufacturing Light Emitting Diodes Including Barrier Layers/Sublayers,” which are assigned to the assignee of the present invention, and the disclosures of which are incorporated herein by reference.

In a typical process, a flux is applied to a mounting surface on which an electronic device is to be mounted. A flux is a chemical cleaning agent that facilitates soldering by removing oxidation from the metals to be joined and/or preventing oxidation during the soldering process. Flux also allows solder to flow easily on the metal surfaces being joined. Flux may also assist with heat transfer between the metal surfaces during the soldering process.

Typically, an electronic die including a solderable metal layer is placed in contact with the mounting surface and the flux, and the temperature of the structure is increased in an inert atmosphere beyond the melting point of the solder, causing the solder to reflow. As the flux and unreflowed solder heats up, the flux wicks away and evaporates, leaving the solder metal behind to join the die to the mounting surface. The temperature of the structure is decreased, causing the solder to harden and form a bond between the mounting surface and the die.

When an electronic component, such as an LED die, is soldered to a submount, voids can form between the die and the submount. Such voids can increase the thermal and/or electrical resistance between the die and the submount, and can also weaken the mechanical strength of the bond between the die and the submount. Increasing the electrical resistance of the package can reduce the overall efficiency of the package, thereby decreasing the number of lumens produced per watt of electrical energy applied to the package. Increasing the thermal resistance of the package can cause the operating temperature of the device to increase, which can reduce the reliability of the package and/or can shift the color of light emitted by the LED. Accordingly, it is generally desirable to avoid the formation of voids between an electronic component and the underlying submount.

### SUMMARY

A packaged electronic device according to some embodiments includes a submount, a bonding pattern on the submount, and an electronic chip on the bonding pattern. A periphery of the electronic chip defines a die mounting region of the submount. The bonding pattern may include a bonding area within the die mounting region and at least one channel that extends from within the die mounting region to a region of the submount outside the die mounting region.

The electronic chip may have an area of at least about 1 mm². at least 1.8, at least 2.25, at least about 3 In some embodiments, the electronic chip may have an area of at least about 1.8 mm², in further embodiments at least about 2.25 mm², and in further embodiments at least about 3 mm². In some further embodiments, the electronic chip may have an area of at least about 4 mm², and in still further embodiments at least about 9 mm². In some embodiments the electronic chip may have dimensions of about 1 mm×1 mm, about 1.4 mm×1.4 mm, about 1.75 mm×1.75 mm, about 2 mm×2 mm, about 3 mm×3 mm, or larger. The chip may have a square, rectangular, triangular, or irregular peripheral shape.

The bonding pattern may include a plurality of bond pads within the die mounting region.

The bonding pattern may include a metal trace, and the at least one channel may include a region of the submount that may be free of the metal trace.

The electronic chip may include an LED chip having a first side and a second side opposite the first side, the first side may be adjacent the submount and the second side may be disposed away from the submount, the LED chip including a metal stack on the first side including an ohmic layer on the LED chip, a barrier layer on the ohmic layer opposite the LED chip, and a bonding layer on the barrier layer opposite the LED chip, the bonding layer may include AuSn, Sn, SnAg, SnAgCu, SnPb, and/or SnPbAg.

The metal stack may further include a reflective layer on the barrier layer opposite the LED chip. The reflective layer may further include a plurality of vias therethrough.

The electronic chip may include an LED chip having a first side and a second side opposite the first side, the first side may be adjacent the submount and the second side may be disposed away from the submount, the LED chip including a phosphor loaded matrix material on the second side of the LED chip.

A method of forming a packaged electronic device according to some embodiments includes providing a submount including a bonding pattern on a surface thereof. The bonding pattern may include a bonding area within a die mounting region of the submount and at least one channel that extends from within the die mounting region to a region of the submount outside the die mounting region. The methods further include dispensing a solder flux on the bonding pattern, and mounting an electronic chip on the bonding pattern. A periphery of the electronic chip defines the die mounting region of the submount, and the electronic chip includes a bonding metal on a surface thereof that contacts the bonding pattern. The bonding metal is reflowed to bond the electronic chip to the bonding pattern.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIGS. 1 and 2 are cross sectional diagrams that illustrate solder bonding of a large area LED die to a submount including conventional metallization.

FIGS. 3A, 3B, 4A and 4B are plan view X-ray images of mounted large area LED dice.

FIG. 5 is a profile measurement of a mounted, non-phosphor coated, LED.

FIG. 6 is a profile measurement of a mounted phosphor coated LED.

FIG. 7 is a cross sectional diagram that illustrates solder bonding of a large area LED die to a submount according to some embodiments.

FIG. 8 is a plan view of a submount according to some embodiments.

FIGS. 9 and 10 are plan view X-ray images of mounted large area LED dice according to some embodiments.

FIGS. 11A to 11E are plan views of submounts according to further embodiments.

FIGS. 12 and 13 are cross sectional diagrams that illustrate flip-chip solder bonding of a large area LED die to a submount according to some embodiments.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

As noted above, voids can form between an electronic device die and a submount when the die is soldered to the submount. Such voids are undesirable, as they can increase the thermal and/or electrical resistance between the die and the submount, and can also weaken the bond between the die and the submount. For small area dice, these voids are typically negligible, and may not materially affect the properties of the bond. However, voiding can be a significant problem when mounting large area devices, such as devices having an area greater than about 1 mm².

Voiding can be a particular problem for LED chips that have been coated with a phosphor matrix, such as a phosphor loaded silicone matrix, that may have a significantly different coefficient of thermal expansion than the semiconductor materials that form the LED active region and/or substrate.

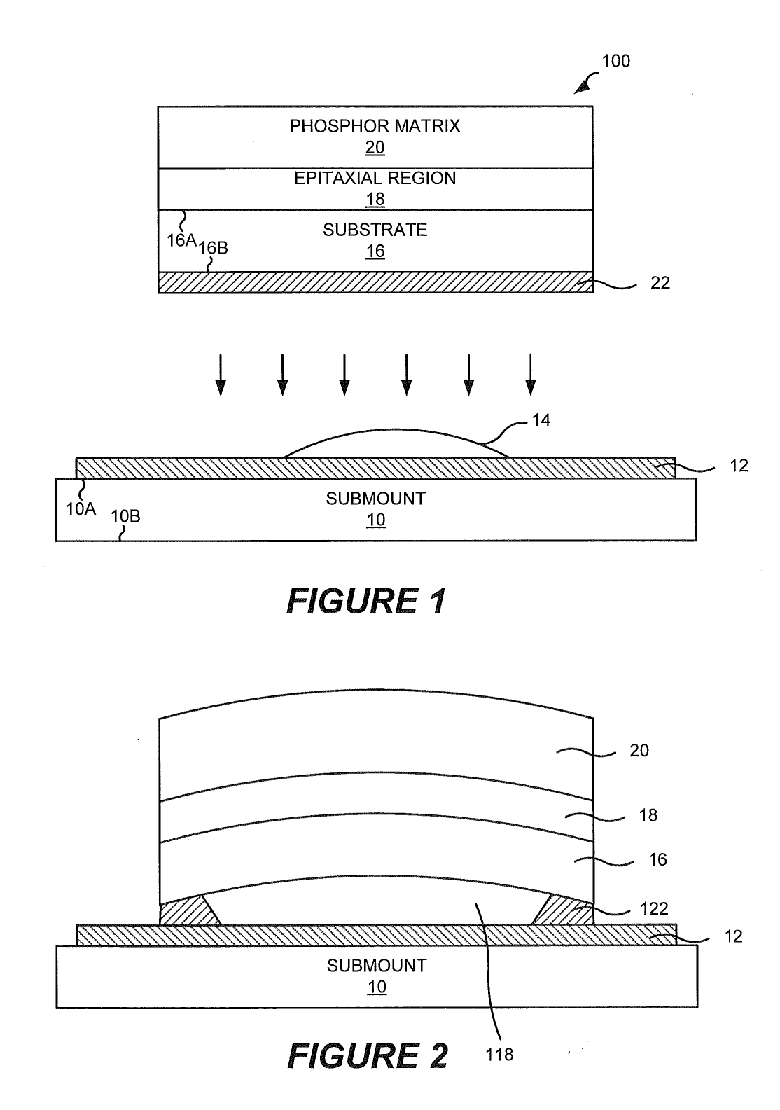

FIGS. 1 and 2 are cross sectional diagrams that illustrate solder bonding of a large area LED die to a submount including conventional metallization. As shown therein, a light emitting device 100 is to be solder bonded to a submount 10. The device 100 includes an optional substrate 16 having first and second opposing faces 16A, 16B. The substrate 16 may be a growth substrate or a carrier substrate on which the epitaxial layers of the LED 100 have been mounted. The substrate 16 may include SiC, Si, sapphire, Cu, GaAs, Ge, AlN, Al₂O₃ or any other suitable substrate material.

In the embodiments illustrated in FIGS. 1 and 2, an epitaxial region 18 is on a first face 16A of the substrate, and a metal stack including a solderable bonding metal 22 is on a second face of the substrate 16B opposite the first face 16A. An optional phosphor matrix 20 may be on the epitaxial region 18 opposite the substrate 16. The phosphor matrix may include, for example, silicone in which particles of a wavelength conversion phosphor, such as a yttrium-aluminum-garnet (YAG) phosphor are embedded.

In other embodiments, the bonding metal 22 may be on the epitaxial region 18 opposite the substrate 16, and the optional phosphor matrix 20 may be on the substrate 16 opposite the epitaxial region 18, so that the LED 100 is provided in a flip-chip configuration. Other configurations of the LED 100 are contemplated within the scope of the invention.

The submount 10 may include a slab of a material which may include a ceramic, such as alumina, aluminum oxide (Al2O3) or AlN, or could be a PCB or metal submount, or MC-PCB or any other acceptable submount. The submount 10 has a first face 10A and a second face 10B. A metal trace 12 is formed on the first face 10A of the submount 10. The metal trace 12 may comprise a conductive material, such as copper, and may have a thickness from about 2 μm to about 70 μm or more.

Prior to soldering, a quantity of flux 14 is applied to the metal trace 12 in the location where the device 100 is to be solder bonded. The device 100 is then brought into contact with the submount 10 and the electrical trace 12, and the structure is heated, causing the bonding metal 22 to reflow (melt).

While not wishing to be bound by a particular hypothesis, the inventors presently believe that when the LED device 100 is heated, a difference in coefficient of thermal expansion between the phosphor matrix 20 and the substrate 16/epitaxial region 18 causes the device 100 to bow slightly, creating a voided region 118 between the device 100 and the electrical trace 12, as shown in FIG. 2. The reflowed bonding metal 22 tends to flow outward toward the periphery of the LED 100. When the structure is cooled below the melting point of the reflowed bonding metal, the structure freezes in place with a large void 118 between the LED 100 and the submount 10, and forming a metal solder bond 122 at the periphery of the LED 100.

This bowing and voiding phenomenon appears most prominently with large area LED dice on which a phosphor matrix is coated, and is not readily evident on large devices on which no phosphor matrix is present. However, embodiments as described herein are not so limited.

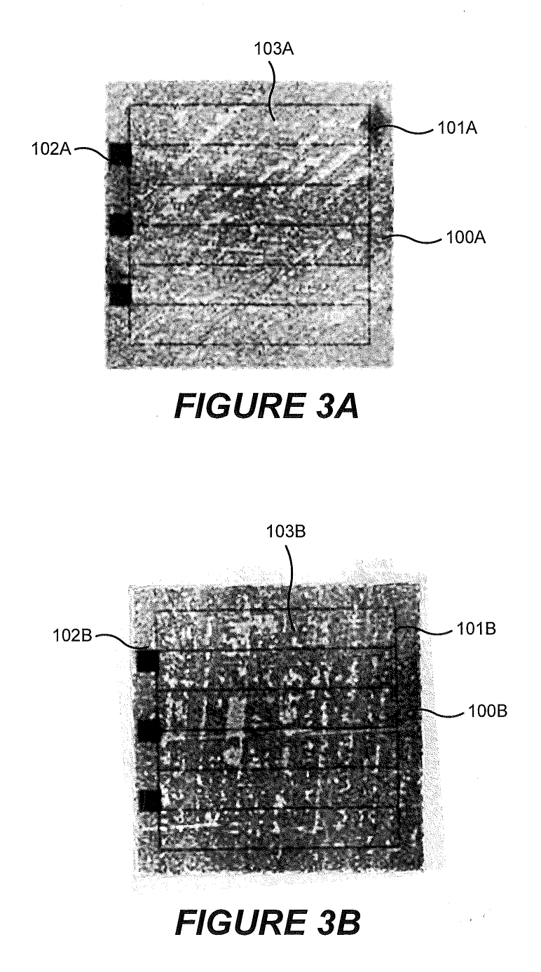

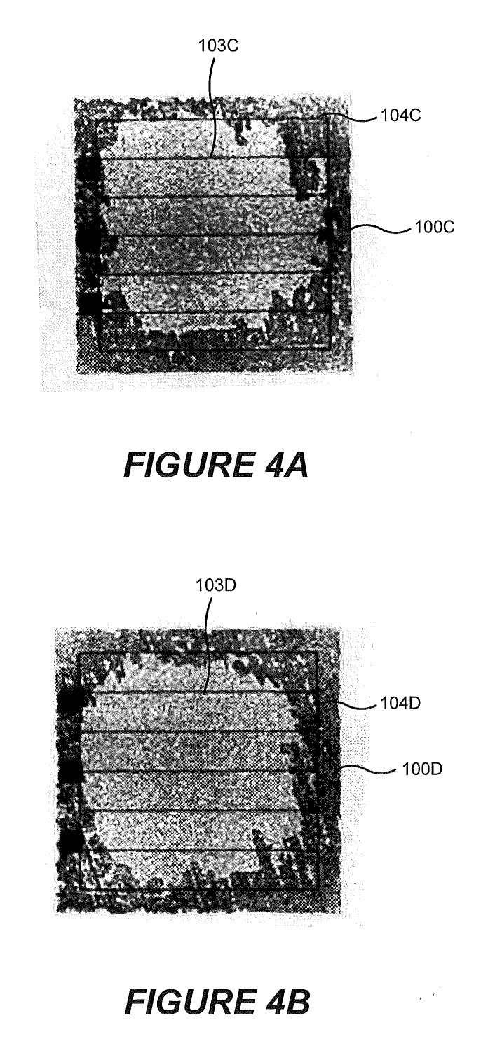

FIGS. 3A, 3B, 4A and 4B are plan view X-ray images of mounted large area LED dice. In particular, FIGS. 3A and 3B are plan view x-ray images of mounted large area LED dice 100A, 100B that do not include a phosphor coating. In the x-ray images of FIGS. 3A and 3B, current spreading fingers 101A, 101B are evident along with wire bonding pads 102A, 102B. Small voids 103A, 103B appear as lighter colored portions in the x-ray images. However, these voids represent a small percentage of the overall area of the LED dice 100A, 100B, and may not significantly affect the electrical, thermal and structural properties of the device.

In contrast, FIGS. 4A and 4B are plan view x-ray images of mounted large area dice 100C, 100D that include a phosphor coating thereon. These images show very large void voiding areas 103C, 103D, with metal bonding regions 104C, 104D only at the periphery of the chips. The thermal and/or electrical resistance of these devices may be high compared to devices that do not include such voids.

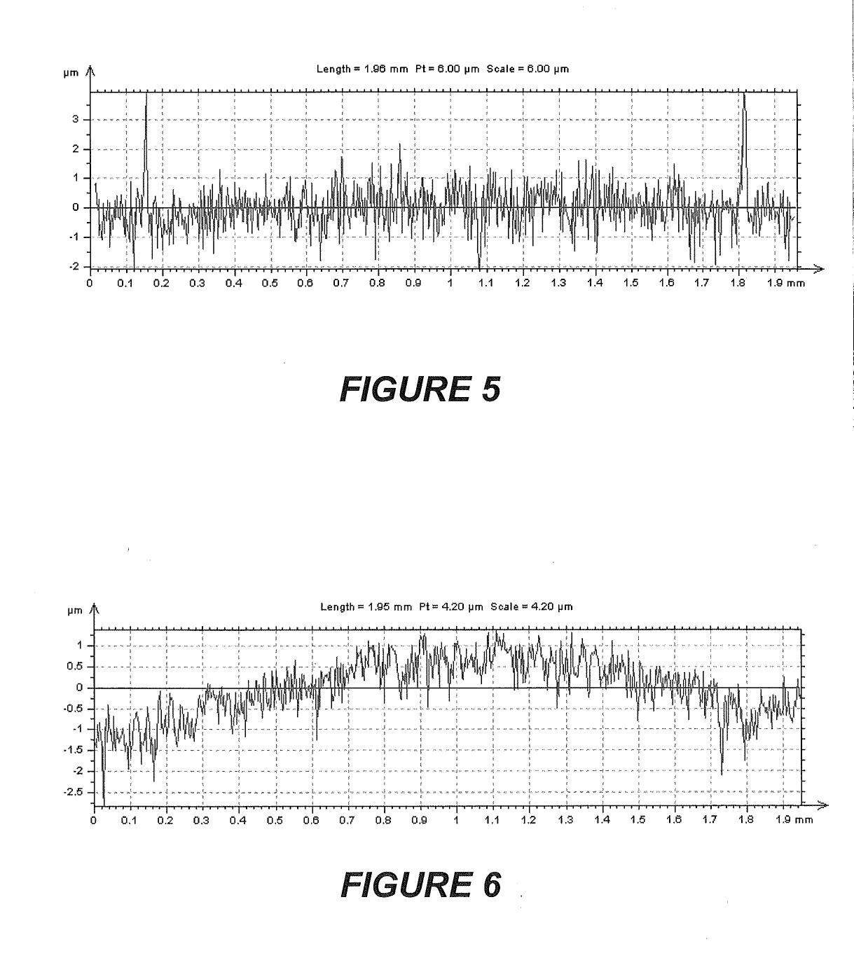

FIG. 5 is a profile measurement of a mounted, non-phosphor coated, LED, while FIG. 6 is a profile measurement of a mounted phosphor coated LED. The profile of the non-phosphor coated LED is substantially flat, while the profile of the phosphor coated LED shows substantial bowing from one end to another.

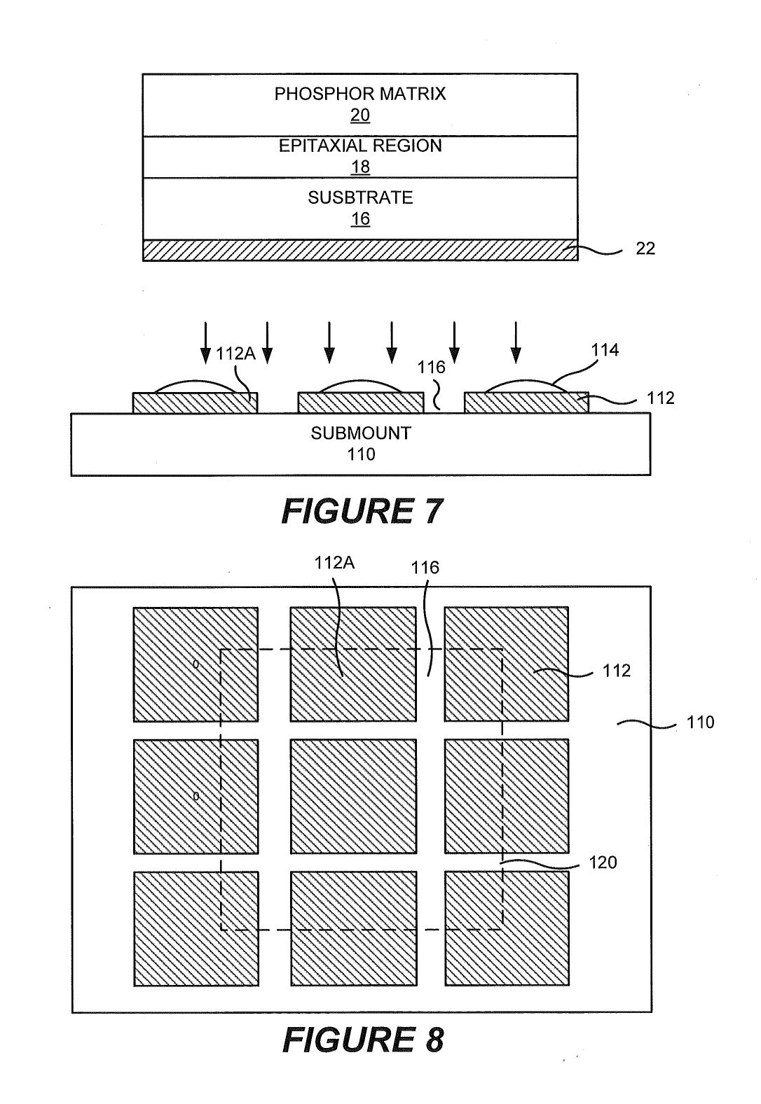

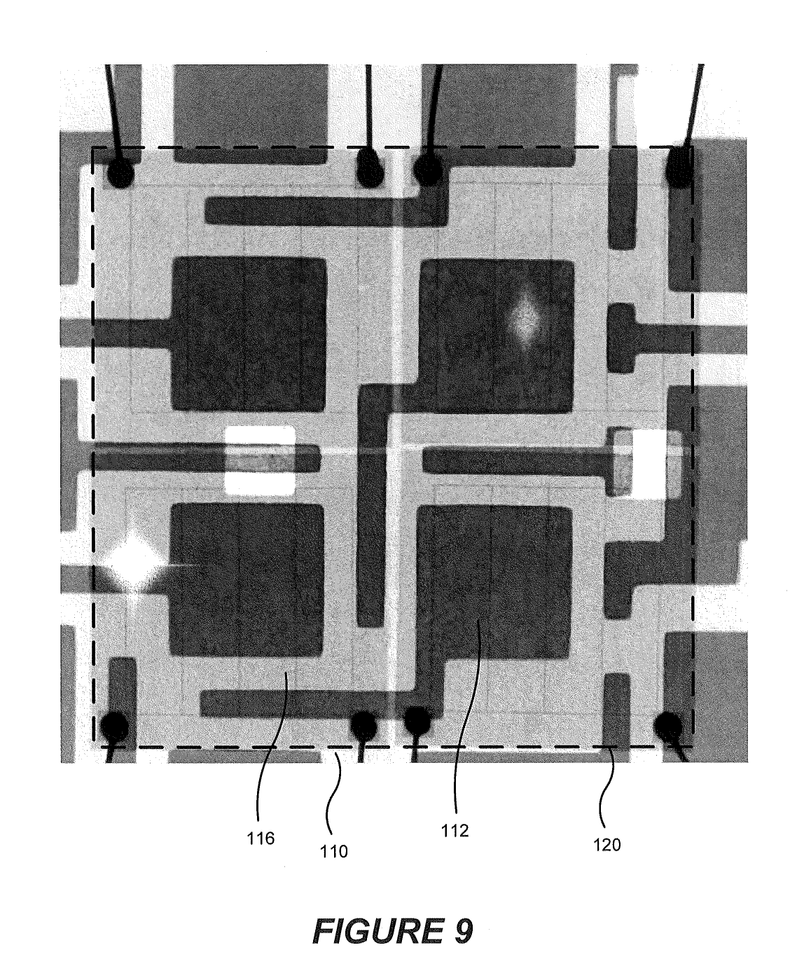

FIG. 7 is a cross sectional diagram that illustrates solder bonding of a large area LED die 100 to a submount 110 according to some embodiments, and FIG. 8 is a plan view of the submount 110. Referring to FIGS. 7 and 8, the submount 110 includes a bonding pattern 112 thereon. The bonding pattern 112 may include a metal trace including one or more bonding areas, such as bond pads 112A. The metal trace may include copper and may have a thickness of about 5 μm to about 70 μm or more.

Referring to FIG. 8, a periphery of the LED die 100 defines a die mounting region 120 of the submount 110. As shown in FIG. 8, the LED die may covers portions of a plurality of the bond pads in some embodiments. The bonding pattern 112 includes at least one channel 116 between adjacent bond pads 112A. In some embodiments, a plurality of channels 116 may be formed. In other embodiments discussed below, the channels 116 may not extend outside the die mounting region 120.

In some embodiments, the channel 116 extends from within the die mounting region 120 to a region of the submount 110 outside the die mounting region 120. The channel 116 may include a region of the submount that is free of the metal trace that forms the bonding pattern 112.

To bond the device 100 to the submount 110, a quantity of flux may be blanket deposited on the submount 110 including the bonding pattern 112 and the channel 116. In some embodiments, flux may be selectively applied to the bond pads 112A.

While not wishing to be bound by any particular theory, it is presently believed that when the device 100 is placed in contact with the submount 110 and heated to reflow the solder, flux can escape through the channels, permitting the solder metal to contact the bond pads 112A and allowing the device 100 to more fully adhere to the bond pads 112A. It is also possible that due to the presence of the channels, the reflowed solder metal becomes dispersed and does not have enough volume in any one location to allow the device 100 to “float” on the reflowed solder at the edges of the device 100. The device 100 may therefore sink down and contact the bond pads 112A more closely. In any case, the fusing of the device 100 to the bond pads 112A by virtue of the channels 116 may overcome the tendency of the devices to bow, resulting in a flatter profile upon cooling.

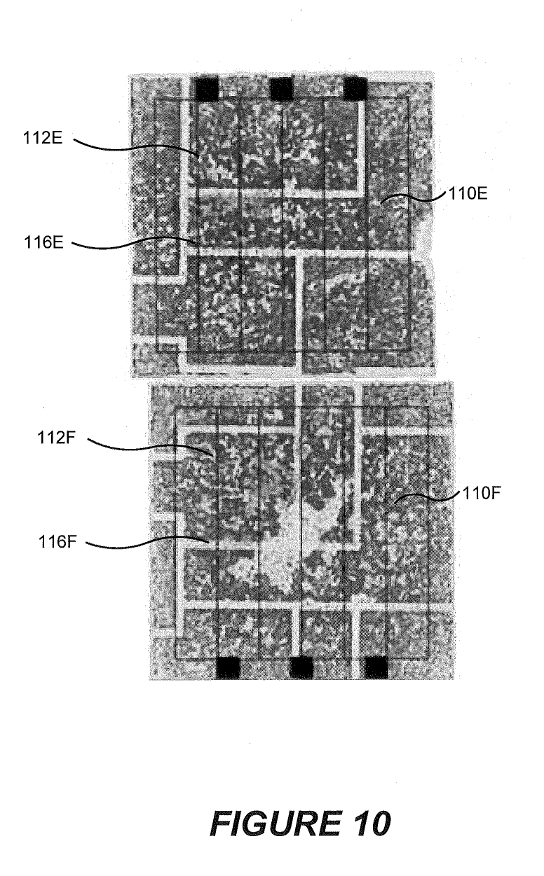

FIGS. 9 and 10 are plan view x-ray images of mounted large area LED dice according to some embodiments. In FIG. 9, the die mounting region 120 defined by the periphery of the LED die is outlined by a dashed line. The submount 110 includes a plurality of bond pads 112A forming a bonding pattern 112. A plurality of channels 116 are between the bond pads 112A and extend from within the die mounting region 120 to locations outside the die mounting region 120. The bonding pattern may be formed by electroplating or by electroless plating. In some embodiments, the channels may be at least about 20 μm in width. In other embodiments, the channels may be at least about 100 μm in width. In still other embodiments, the channels may be at least about 150 μm in width. In still other embodiments, the channels may be at least about 200 μm in width.

The x-ray image of FIG. 9 shows negligible voiding on the bond pads 112A.

In FIG. 10, LEDs 100E and 100F are mounted on submounts 110 that include bonding patterns 120 that are formed by very thin (<5 μm) copper traces formed by electroless plating. With electroless plating, the channels 116E, 116F on such submounts 110 may be formed to have a very narrow width, e.g., less than 100 nm in width, and in some cases less than 20 nm in width. However, as noted above, the channels may be formed to be about 20 μm in width or more in some embodiments.

The x-ray image of FIG. 9 shows a small amount of voiding on the bond pads 112E, 112F.

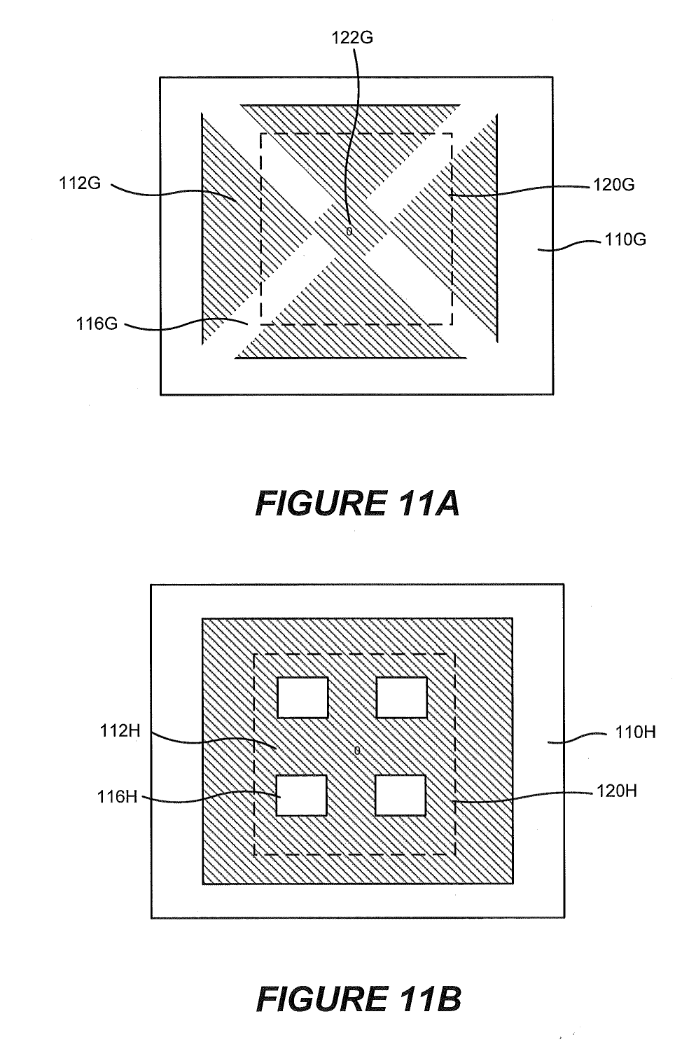

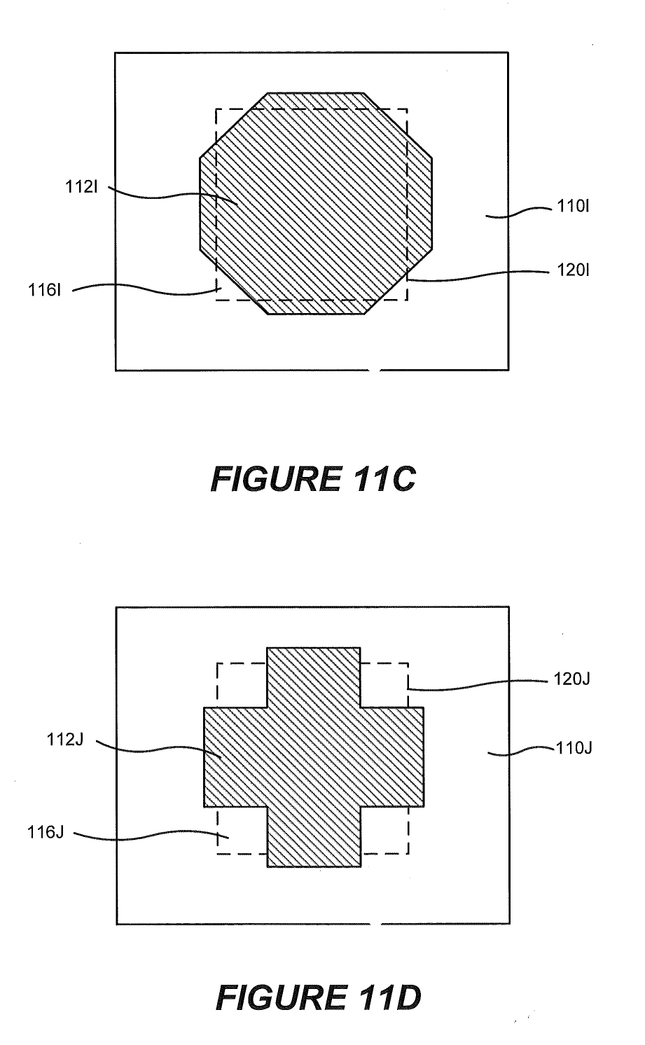

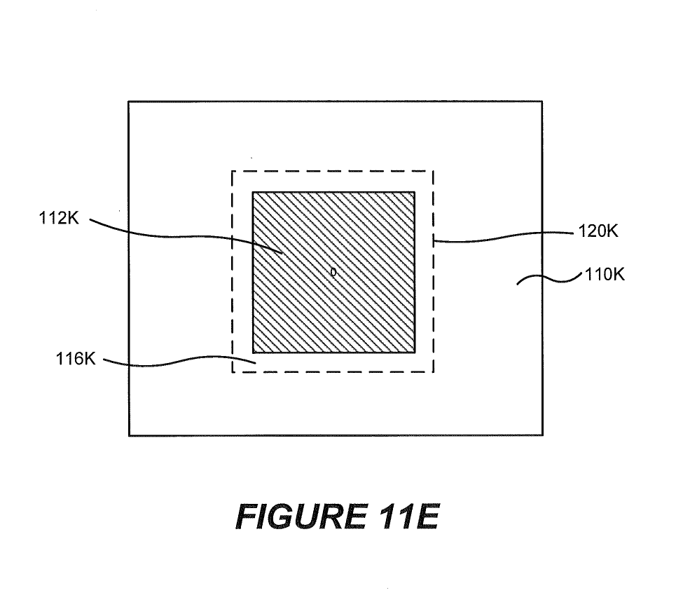

FIGS. 11A to 11D are plan views of submounts according to further embodiments. Referring to FIG. 11A, the submount 110G includes a bonding pattern 112G including a central region 122G and a plurality of channels 116G that extend from proximate the central region 122G to locations outside the die attach area 120G.

FIG. 11B illustrates a submount 110H including a bonding pattern 112H. The bonding pattern 11211 includes a plurality of engineered voids 116H that are contained entirely within the periphery of the die mounting region 120H and do not extend outside the die mounting region 120H. Having engineered voids 11611 only within the periphery of the die mounting region may not provide the best performance, however.

FIGS. 11C and 11D illustrate a substrates 110I, 110J including bonding patterns 112I, 112J that fill the die attach regions 120I, 120J except for corners thereof, while FIG. 11E illustrates a substrate 110K including a bonding pattern 112K that fills the die attach region 120K except for peripheral edges thereof.

Some embodiments may include both channels 116G extending from inside to outside the die attach area as shown in FIG. 11A, as well as engineered voids 116H that are contained entirely within the periphery of the die mounting region as shown in FIG. 11B. Similarly, some embodiments may include channels 116G extending from inside to outside the die attach area as shown in FIG. 11A, as well as engineered voids at the edges or corners of the die attach region. Many different combinations of the foregoing features are contemplated.

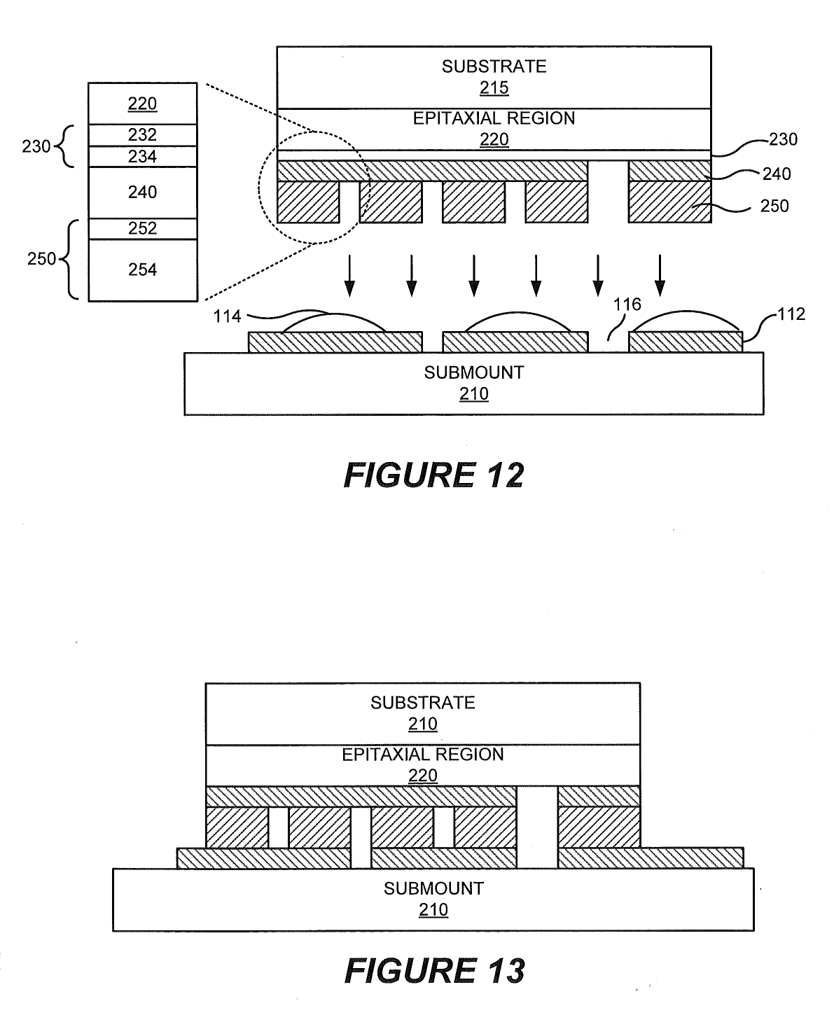

FIGS. 12 and 13 are cross sectional diagrams that illustrate flip-chip solder bonding of a large area LED die to a submount according to some embodiments. An LED chip 200 that is configured for flip-chip (e.g. substrate up) mounting may include both anode (+) and cathode (−) contacts on the same side of the chip. FIG. 12 (inset) also illustrates a metal stack for bonding an LED to a submount according to some embodiments. The LED 200 includes a substrate 215 on which an epitaxial region 220 is provided. The substrate may be a growth substrate or a carrier substrate on which the epitaxial region 220 has been bonded. A metal stack is formed on the epitaxial region 220 opposite the substrate and includes an ohmic structure 230 including an ohmic layer 232 on the epitaxial region 220 and a barrier layer 234 on the ohmic layer 232. The ohmic layer 232 may include platinum, and the barrier layer 234 may include Ti, TiW and/or Ni.

A reflector 240 is on the ohmic structure 230. The reflector 240 may include aluminum and/or silver. A bonding structure 250 is on the reflector 240 and includes a thin layer 242 of Au and a thicker layer 254 of AuSn. When the solder metal is reflowed, the Au from the thin layer 242 may alloy with the AuSn of the layer 254 to form a eutectic that has a higher melting point. Metal stacks for LEDs are described in more detail in the above-referenced U.S. Pat. Nos. 7,642,121 and 7,259,033, as well as U.S. Publication No. 2007/0161137.

The device 200 may include a plurality of openings 236 through the bonding structure 250 and the reflector 240.

One problem that can occur when performing flip-chip mounting of large area devices is that the anode (+) contact of the device 200 may bond well to the anode trace on the submount 210, but the cathode (−) contact of the device may not bond well to the cathode trace on the submount 210.

While not wishing to be bound by a particular hypothesis, it is presently believed that after reflow, the device 200 may “float” on the reflowed solder under the anode (+) contact, which may pull the device away from the submount 210 and interfere with bonding the anode (−) contact to the smaller anode trace on the submount 210. Providing channels or engineered voids 216 in the bonding pattern 212 of the submount 210 may allow the device 200 to sink down so that good contact, and thereby good bonding, may be made to both the anode and cathode contacts of the device 200, as shown in FIG. 13.

According to some embodiments, controlled voids are engineered into a submount/electronic device interface to reduce or prevent uncontrolled voiding that can increase the thermal and/or electrical resistance of the solder connection between the submount and device. Controlled voiding is introduced by providing regions in a die attach area (i.e., the area of the substrate within the periphery of the mounted device) that are free of the bond pad metal. However, it will be appreciated that there is a tradeoff between the amount of voiding that is introduced and the thermal and electrical resistance of the device, as well as current density through the contact. As more surface area of the substrate within the die mounting region is taken up by engineered voids and/or channels, less of the area within the die mounting region is used to attach the device to the substrate.

In general, it has been found that a coverage ratio of metallized to total area of the die mounting region of about 0.3 to 0.95 may achieve desired results. For example, for a 1 mm×1 mm die attach area (corresponding to a 1 mm×1 mm chip), the metallized portion of the bonding pattern may occupy about 0.3 mm² to about 0.95 mm² of the die attach area. A coverage ratio of about 0.33 to 0.9 may be more preferable. The amount of coverage required may be affected by the placement of the channels/engineered voids. For example, it has been found that placing channels/engineered voids near the periphery of the die attach region may yield excellent results. In some embodiments, a coverage ratio of metallization in the die attach area may be less than about 0.7, and in some cases may be less than about 0.5. In some embodiments, the coverage ratio of metallization in the die attach area may be between about 0.3 and 0.7, and in some cases may be between about 0.4 and 0.5.

A coverage ratio of about 0.4 under a 2 mm² chip with engineered voids at the periphery of the die attach region has been found to result in good attachment. However, a coverage ratio of 0.95 may not result in as good attachment, although it may result in improvement over bonding to a flat plane.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

Although embodiments have been described with respect to light emitting diodes and packaging thereof, the present invention may be advantageously employed in connection with other types of semiconductor devices, including power and microwave devices, that are mounted on submounts and that generate heat during operation.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A packaged electronic device according to some embodiments comprises:
a submount,
a bonding pattern on the submount, and
an electronic chip on the bonding pattern;
wherein a periphery of the electronic chip defines a die mounting region of the submount, and wherein the bonding pattern comprises a bonding area within the die mounting region and at least one channel that extends from within the die mounting region to a region of the submount outside the die mounting region.

2. The packaged electronic device of claim 1, wherein the bonding pattern comprises a plurality of bond pads within the die mounting region.

3. The packaged electronic device of claim 1, wherein the bonding pattern comprises a metal trace, and the at least one channel comprises a region of the submount that is free of the metal trace.

4. The packaged electronic device of claim 1, wherein the electronic chip comprises an LED chip having a first side and a second side opposite the first side, wherein the first side is adjacent the submount and the second side is disposed away from the submount, the LED chip comprising a metal stack on the first side comprising an ohmic layer on the LED chip, a barrier layer on the ohmic layer opposite the LED chip, and a bonding layer on the barrier layer opposite the LED chip.

5. The packaged electronic device of claim 4, wherein the bonding layer comprises AuSn, Sn, SnAg, SnAgCu, SnPb, and/or SnPbAg.

6. The packaged electronic device of claim 4, wherein the metal stack further comprises a reflective layer on the barrier layer opposite the LED chip.

7. The packaged electronic device of claim 6, wherein the reflective layer further comprises a plurality of vias therethrough.

8. The packaged electronic device of claim 1, wherein the electronic chip comprises an LED chip having a first side and a second side opposite the first side, the first side is adjacent the submount and the second side is disposed away from the submount, the LED chip comprising a phosphor loaded matrix material on the second side of the LED chip.

9. The packaged electronic device of claim 1, wherein the electronic chip has an area of at least about 1 mm2.

10. The packaged electronic device of claim 1, wherein the electronic chip has an area of at least about 3 mm2.

11. The packaged electronic device of claim 1, wherein the electronic chip has an area of at least about 9 mm2.

12. The packaged electronic device of claim 1, wherein the electronic chip has dimensions of about 1 mm×1 mm.

13. The packaged electronic device of claim 1, wherein the electronic chip has a square, rectangular, triangular, or irregular peripheral shape.

14. A packaged electronic device according to some embodiments comprises:
a submount,
a metal bonding pattern on the submount, and
an electronic chip on the metal bonding pattern;
wherein a periphery of the electronic chip defines a die mounting region of the submount, and wherein the submount is free of the metal bonding pattern in at least a portion of the die mounting region.

15. The packaged electronic device of claim 14, wherein the metal bonding pattern comprises a plurality of channels that extend from inside the die mounting region to a portion of the submount outside the die mounting region.

16. The packaged electronic device of claim 14, wherein the metal bonding pattern comprises a plurality of engineered voids within the die mounting region.

17. The packaged device of claim 16, wherein the engineered voids overlap an edge of the die mounting region.

18. The packaged device of claim 16, wherein the engineered voids are disposed within a periphery of the die mounting region.

19. The packaged device of claim 14, wherein a ratio of metalized area to total area of the die mounting region is between about 0.3 and 0.95.

20. The packaged device of claim 19, wherein the ratio of metalized area to total area of the die mounting region is less than about 0.7.

21. The packaged device of claim 19, wherein the ratio of metalized area to total area of the die mounting region is between about 0.3 and 0.7.

22. The packaged device of claim 19, wherein the ratio of metalized area to total area of the die mounting region is between about 0.4 and 0.5.

23. A method of forming a packaged electronic device according to some embodiments comprises:
providing a submount comprising a bonding pattern on a surface thereof, wherein the bonding pattern comprises a bonding area within a die mounting region of the submount and at least one channel that extends from within the die mounting region to a region of the submount outside the die mounting region; and
dispensing a solder flux on the bonding pattern, and mounting an electronic chip on the bonding pattern, wherein a periphery of the electronic chip defines the die mounting region of the submount, and the electronic chip comprises a bonding metal on a surface thereof that contacts the bonding pattern; and
reflowing the bonding metal to bond the electronic chip to the bonding pattern.
